(19) United States
(12) Patent Application Publication
(10) Pub. No.: US 2015/0270469 A1
(43) Pub. Date: Sep. 24, 2015

(54) Thermoelectric Converting Element

(71) Applicant: Kabushiki Kaisha Toshiba, Tokyo (JP)

(72) Inventors: Hiromi YUASA, Kawasaki (JP); Masaki KADO, Yokohama (JP)

(73) Assignee: Kabushiki Kaisha Toshiba

(21) Appl. No.: 14/660,096

(22) Filed: Mar. 17, 2015

(30) Foreign Application Priority Data
Mar. 19, 2014 (JP) 2014-057235

(51) Int. Cl. H01L 37/00

(52) U.S. Cl. CPC H01L 37/00

(57) ABSTRACT

A thermoelectric converting element includes a substrate, a nonmagnetic metal layer, and an insulated ferromagnetic layer provided between the substrate and the nonmagnetic metal layer and having a magnetization fixed in a plane in a direction and including a hard magnetic material.

### CROSS-REFERENCE TO RELATED APPLICATION

This application is based upon and claims the benefit of priority from Japanese Patent Application No. 2014-057235, filed Mar. 19, 2014; the entire contents of which are incorporated herein by reference.

### FIELD

Embodiments described herein relate to a thermoelectric converting element.

### BACKGROUND

As one of thermoelectric converting elements, there has been known a thermoelectric converting element using a spin Seebeck effect. The thermoelectric converting element gains electromotive force in a condition that an external magnetic field is applied to the thermoelectric converting element. However, for a practical purpose, the thermoelectric converting element should be usable without using the external magnetic field.

### DESCRIPTION OF THE DRAWINGS

FIG. 1 is a diagram for showing a thermoelectric converting element according to an embodiment of the present invention.

FIG. 2 is a diagram for showing a thermoelectric converting element according to an embodiment of the present invention;

FIG. 3A is a diagram for showing a schematic diagram of a condition of a magnetization of an insulated ferromagnetic layer;

FIG. 3B is a diagram for showing a schematic diagram of a condition of a magnetization of an insulated ferromagnetic layer;

FIG. 4A is a diagram for showing a related art of a thermoelectric converting element;

FIG. 4B is a diagram for illustrating a relationship between an external magnetic field and magnetization;

FIG. 5A is a diagram for showing an electromotive force that a thermoelectric converting element generates in the case where an external magnetic field is applied to an insulated ferromagnetic material;

FIG. 5B is a diagram for showing an electromotive force that a thermoelectric converting element generates in the case where an external magnetic field applied to an insulated ferromagnetic material;

FIG. 6 is a diagram for showing results of detecting electromotive force of thermoelectric converting elements;

FIG. 7 is a diagram for showing a plot of results shown table 2 for comparative example 1 and working examples 1 and 2; and

FIG. 8 is a diagram for showing a thermoelectric converting element.

### DETAILED DESCRIPTION

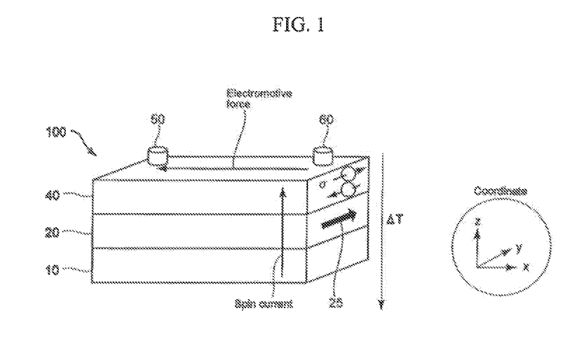

Hereinafter, with reference to the accompanying drawings, embodiments will be described. What is given the same reference numeral indicates the same component. It is noted that the drawings are schematic or conceptual and that a relationship between a thickness and a width of each portion and a ratio coefficient of sizes between the portions are not necessarily the same as those of actual things. Moreover, even when the same portion is shown, there is also a case where it is shown with different sizes and ratio coefficients depending on the drawings. FIG. 1 is a diagram showing a thermoelectric converting element 100. The thermoelectric converting element 100 is configured such that an insulated ferromagnetic layer 20 having a ferrite magnet and a nonmagnetic metal layer 40 are provided in this order on a substrate 10. Layers 20 and 40 may be characterized as a laminated body. Furthermore, terminals 50, 60 are provided on the nonmagnetic metal layer 40.

An operating principle of the thermoelectric converting element 100 will be explained. The thermoelectric converting element 100 can generate electricity by using the spin Seebeck effect.

If a temperature gradient ΔT is applied to the insulated ferromagnetic layer 20 between the substrate 10 and the nonmagnetic metal layer 40, there occurs a difference between a distribution of up spin electrons and down spin electrons in the insulated ferromagnetic layer 20. This phenomenon is referred to as the spin Seebeck effect, and this occasional difference between the distribution of up spin electrons and the distribution of down spin electrons is referred to as a spin pressure. The spin pressure that arises in the insulated ferromagnetic layer 20 propagates into the nonmagnetic metal layer 40. A spin current is a flow that arises from the difference between the distribution of up spin electrons and the distribution of down spin electrons, and is not a flow of electric charges. When the spin current propagates into the nonmagnetic metal layer 40, an inverse spin Hall effect causes an electric current, which is a flow of electric charges, to flow in a direction perpendicular to the spin current and a magnetization 25 of the insulated ferromagnetic layer 20, which generates an electromotive force. By this, the thermoelectric converting element 100 generates electricity.

The substrate 10 and the insulated ferromagnetic layer 20 can make contact: with one another. The insulated ferromagnetic layer 20 and the nonmagnetic metal layer 40 can make contact with one another. That respective layers adjoin other layers in this way can enable the spin current to propagate into the nonmagnetic metal layer 40.

A flexible substrate is used for the substrate 10 in order to enable generating electricity on a comparatively large area by making use of every heat generation surface. The substrate 10 preferably has flexibility with a Young's modulus being less than or equal to 10. Polyimide, polypropylene, nylon, polyester, parylene, a rubber, a biaxially stretched polyethylene-2,6-naphthalate, or a modified polyamide may be used for the substrate 10. In the case where there is no need for flexibility for the substrate 10, Si, glass, or sapphire can be used for the substrate 10. In the case where the insulated ferromagnetic layer 20 has at least 1 μm thickness, the thermoelectric converting element 100 does not need to use the substrate 10.

A material having a large spin Hall angle θ_{SH} suitable for the nonmagnetic metal layer 40. Pt, Ta, or W can be used for the nonmagnetic metal layer 40. Ta having a cubic crystal structure is preferable. This is because the electrical resistivity of the cubic Ta is lower than amorphous Ta. Moreover, tetragonal Ta is further preferable. This is because it has a larger spin Hall angle. Tetragonal Ta is referred to herein β-Ta. When W is used for the nonmagnetic metal layer 40, β-W having the tetragonal crystal structure is preferable. Adding at least one element selected from a group consisting of Hf, W, Ir, Pt, Au, Pb, and Bi to the nonmagnetic metal layer 40 containing Ta will further raise the electromotive force. Similarly, adding at least one element selected from a group consisting of Hf, Ta, Ir, Pt, Au, Pb, and Bi to the nonmagnetic metal layer 40 containing W will further raise the electromotive force. These elements are added to the nonmagnetic metal layer 40 by not less than 3 at % and not more than 30 at %. Each of these elements has a function of increasing a spin orbit interaction in the nonmagnetic metal layer 40 and increasing the spin Hall angle θ_{SH}. For this reason, adding at least one of the elements improves an efficiency of generating the thermoelectric converting element 100

Moreover, at least one element selected from a group consisting of Fe, Co, Ni, Mn, and Cr may be added to the nonmagnetic metal layer 40 containing Pt, Ta or W. These elements are added to the nonmagnetic metal layer 40 by not more than 1 at %. These elements may be added thereto together with another element such as Hf, W, Ta, Ir, Pt, Au, Pb, and/or Bi described above. Since these elements are small in quantity, the nonmagnetic metal layer 40 still remains nonmagnetic as a whole. Since these elements are localized in the nonmagnetic metal layer 40, each of them has a function of increasing the spin orbit interaction and increasing the spin Hall angle θ_{SH}. For this reason, the efficiency of generating the thermoelectric converting element 100 improves. Since the nonmagnetic metal layer 40 detects the spin current, it is also called as a spin current detecting layer.

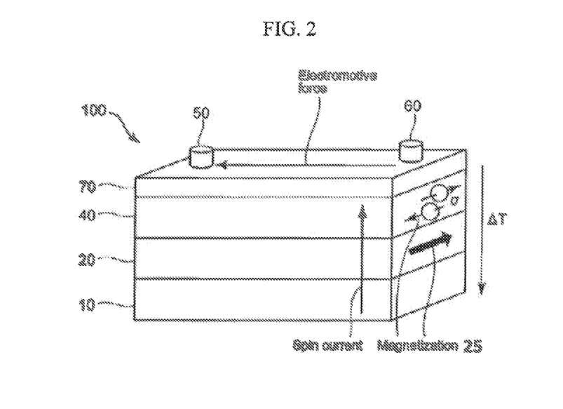

As shown in FIG. 2, a protecting layer 70 can be provided on the nonmagnetic metal layer 40 in order to prevent oxidating the nonmagnetic metal layer 40. Pt, Au, or Ru being not oxidized can be used for a material of the nonmagnetic metal layer 40. An alloy related to these metals or laminating these metals can be used for the nonmagnetic metal layer 40.

A direction of the electromotive force will be explained. The electromotive force is generated in a direction of a cross product between a direction of the magnetization 25 of the insulated ferromagnetic layer 20 and a direction of temperature difference, which is a direction of the spin current. In order to detect the electromotive force from the terminals 50, 60, the magnetization 25 of the insulated ferromagnetic layer 20 is fixed in a direction perpendicular to the direction of temperature difference. FIG. 1 shows a coordinate system for reference. In the case where there is the temperature difference in −z direction (laminating direction) for the thermoelectric converting element 100, the electromotive force generate in the −x is direction when the magnetization 25 is in the +y direction. The temperature difference generate in a direction connecting from the substrate 10 to the nonmagnetic metal layer 40.

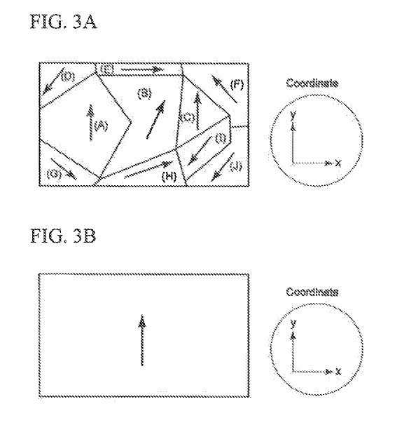

FIGS. 3A and. 3B show a schematic diagram of a condition of the magnetization of the insulated ferromagnetic layer 20 viewed from the z direction of FIG. 1. FIG. 3A shows magnetic domains having different magnetizations in the insulated ferromagnetic layer 20. In this case, the magnetizations of the magnetic domains (A), (B), and (C) are in almost the same +y direction. For this reason, the thermoelectric converting element 100 can generate the electromotive force in the x direction. The magnetizations of the magnetic domains (D), (I), and (J) are in almost the same −y direction. For this reason, the electromotive force is in the +x direction and the electromotive force is canceled by the electromotive force from the magnetic domains (A), (B), and (C). In the case where, as shown in FIG. 3B, the magnetization of the insulated ferromagnetic layer 20 is a single magnetic domain, all magnetizations are in the +y direction. For this reason, the electromotive force is also generated in the −x direction, and the largest amount of the electromotive force can be detected from the terminals 50, 60. The shape of the magnetic domains depends on material and shape. For this reason, FIG. 3A is only exemplary.

As mentioned above, in order to detect the electromotive force efficiently toward the temperature difference, the single magnetic domain being in the direction perpendicular to the direction connecting from the terminal 50 to terminal 60 can be used for the magnetization 25 of the insulated ferromagnetic layer 20.

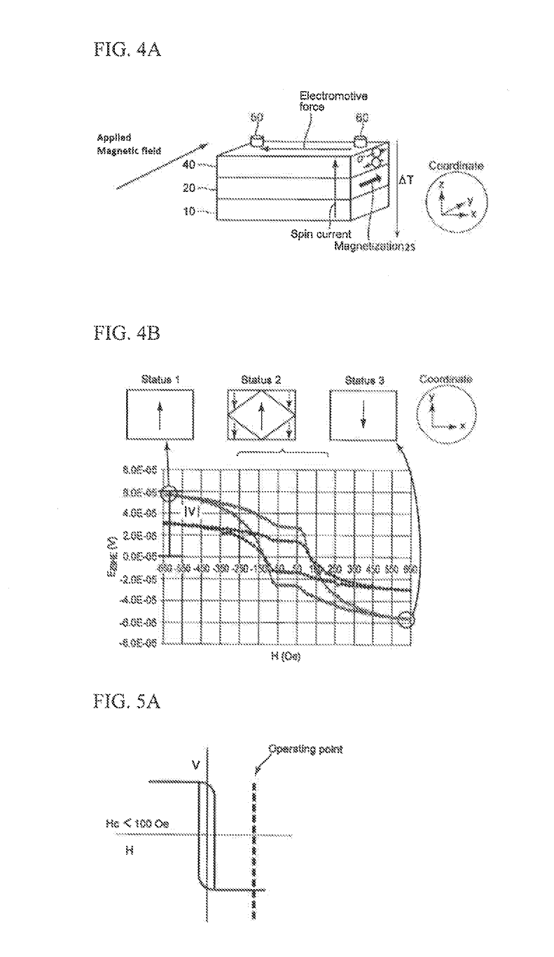

FIG. 4A shows a diagram of related art of a thermoelectric converting element. In order to realize a single magnetic domain in the insulated ferromagnetic layer 20, an external magnetic field is applied to the whole of the thermoelectric converting element in the y direction. The temperature difference is in a laminating direction (z direction) of the thermoelectric converting element. When the terminals 50, 60 are provided along the x direction and the magnetic field is applied in y direction, the electromotive force |V| can be obtained. FIG. 4B illustrates a relationship between an external magnetic field and magnetization. Each status shows a status of magnetization. By doing this, status 1 and status 3 can be realized and the electromotive force can be obtained by the spin Seebeck effect. Here, the electromotive force is generated even in status 2 in which the external magnetic field is not applied. There are two problems. As explained with reference to FIG. 3, the first problem is that the magnetic domain is formed in the status 2 and the value of the electromotive force can be smaller than that the status 1 and the status 3.

As shown in FIG. 4B, the second problem is that magnetization can be rotated or reversed and the electromotive force cannot be obtained when magnetic noise is externally applied because the magnetization is reversed by applying the external magnetic field with about 100 Oe. To avoid this problem, it is necessary that make the insulated ferromagnetic layer 20 a single magnetic domain.

However, in the case where the thermoelectric converting element is used as a power generation element, it is difficult to continuously applying the external magnetic field can be continuingly applied to the thermoelectric converting element. Even if the external magnetic field to the thermoelectric element can be realized, the formation of the power generation element is limited and it will be difficult for the power generation element to be applied to several kinds of applications.

To resolve this, a hard magnetic material is used for the insulated ferromagnetic layer 20.

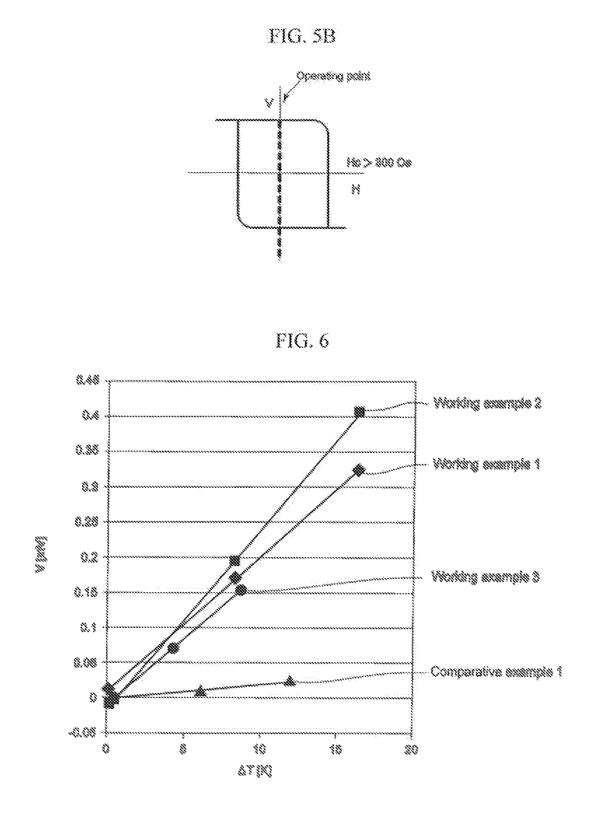

FIG. 5A is a schematic diagram showing the electromotive force that the thermoelectric converting element 100 generates in the case where the external magnetic field is applied to the insulated ferromagnetic material 20 by use of a soft magnetic material having a coercive force with over 100 Oe and lower than 300 Oe. FIG. 5B is a schematic diagram showing the electromotive force that the thermoelectric converting element 100 generates in the case where the external magnetic field is applied to the insulated ferromagnetic material 20 by use of a hard magnetic material having coercive force with over 300 Oe In FIG. 5A, a condition that the magnetization of the insulated ferromagnetic layer 20 is arranged in one direction by applying the external magnetic field to the insulated ferromagnetic layer 20 can be set as an operation point which generates the electromotive force. On the other hand, in FIG. 5B, the operation point can be set in a condition that the external magnetic field is not applied to the insulated ferromagnetic layer 20. As shown in FIG. 5B, if the coercive force (Hc) is not less than 300 Oe, magnetic endurance for the magnetic noise becomes higher because magnetization does not reverse easily. An upper limit of the coercive force is about 4000 Oe because a coercive force of the ferrite is up to about 4000 Oe. If there is a way to realize higher coercive force than this, the hard magnetic material can be used this way. Sufficient coercive force can be realized because an ideal ferrite magnet can realize a coercive force of not less than 300 Oe. Therefore, in this embodiment, a hard magnetic reffered a ferrite magnet can be used for the insulated ferromagnetic layer 20.

An oxide including mainly Fe and at least one element selected from a group of Sr, La, Co, Zn, and Ba can be used for the hard magnetic material. The oxide including mainly Fe means that the hard magnetic material includes Fe not less than 25% at and oxygen not less than 55% at. SrFe₁₂O₁₉, LaFe₁₂O₁₉, LaCo₍ₓ₎Fe₍₁₂₋ₓ₎O₁₉ (0<x<2), Sr_{(y)}La_{(1-y)}Co₍ₓ₎Fe₍₁₂₋ₓ₎O19 (0<x<2, 0<y<1), Sr_{(y)}La_{(1-y)}Zn₍ₓ₎Fe₍₁₂₋ₓ₎O₁₉ (0<x<2, 0<y<1), CoFe₂O₄, or Ni₍ₓ₎Zn₍₁₋ₓ₎Fe₂O₄ (0<x<1) can be used for the insulated ferromagnetic layer 20.

Table 1 shows coercive force of some magnetic materials formed on a thermal silicon oxide substrate. A composition shown in FIG. 6 is insulated ferromagnetic layer/nonmagnetic metal. Table 1 shows a comparison of working examples 1-3 and comparative examples 1-5. Table 1 shows soft magnetism and hard magnetism. Samples were formed by use of sputtering method when forming the insulated ferromagnetic layer and nonmagnetic metal layer formed on the thermal silicon oxide substrate. As shown in Table 1, the working examples 1-3 showed coercive force of not less than 300 Oe. These results are sufficient for a condition of the soft magnetic material. An ion accelerating voltage was set on 1000 V for high power sputtering. The ion accelerating voltage was set on 500 V for low power sputtering.

TABLE 1

| | Composition | Hc [Oe] | |
|---|---|---|---|
| Comparative example 1 | Ni—Zn—Fe—O 100 nm/Pt 10 nm | 100 | Soft magnetism |
| Comparative example 2 | Y₃Fe₅O₁₂ 60 nm/Pt 10 nm | 5 | Soft magnetism |
| Comparative example 3 | Ni_{0.2}Zn_{0.3}Fe_{2.5}O₄ 3 um/Pt 10 nm | 25 | Soft magnetism |
| Comparative example 4 | Co₂MnSi 20 nm/Pt 10 nm | 16 | Soft magnetism |
| Comparative example 5 | Ni₈₁Fe₁₉ 20 nm/Pt 10 nm | 15 | Soft magnetism |
| Working example 1 | Ni—Zn—Fe—O 100 nm/Pt 10 nm | 444 | Hard magnetism |
| Working example 2 | Ni—Zn—Fe—O 200 nm(hign power | 590 | Hard magnetism |
| | sputtering)/Pt 10 nm | | |
| Working example 3 | Ni—Zn—Fe—O 200 nm/(low power | 445 | Hard magnetism |
| | sputtering)Pt 10 nm | | |

Thermoelectric converting elements were fabricated by use of magnetic materials of the comparative example 1 and the working examples 1-3 for the insulating ferromagnetic layer. Table 2 shows the results of detecting spin Seebeck effect of these thermoelectric converting elements without applying the external magnetic field to these thermoelectric converting elements. FIG. 6 shows the results of detecting electromotive force of these thermoelectric converting elements. A horizontal axis shows a temperature difference ΔK between an upper surface and a lower surface of the thermoelectric converting element. A vertical axis shows the electromotive force (mV) detected between two terminals provided on the nonmagnetic metal layer of the thermoelectric converting element. The spin Seebeck coefficient can be calculated from a slope of the apparently characteristic show in FIG. 6.

TABLE 2

| | | | Spin | |
|---|---|---|---|---|
| | | | Seebeck | |
| | | Coercivity | coefficient | |
| | Composition | Hc [Oe] | [μV/Km] | |
| Comparative | Ni—Zn—Fe—O 100 | 90 | 68 | Soft |
| example 1 | nm/Pt 10 nm | | | magnetism |
| Working | Ni—Zn—Fe—O | 445 | 696 | Hard |
| example 1 | 100 nm/Pt 10 nm | | | magnetism |
| Working | Ni—Zn—Fe—O 200 | 590 | 918 | Hard |
| example 2 | nm (high power | | | magnetism |
| | sputtering)/Pt 10 nm | | | |
| Working | Ni—Zn—Fe—O 200 | 444 | 671 | Hard |
| example 3 | nm/(low power | | | magnetism |
| | sputtering) Pt 10 nm | | | |

In the spin Seebeck effect, the electromotive force is divided by a distance between the two terminals (28 mm), and the electromotive force in a unit length and a unit temperature is described as the spin Seebeck coefficient because the distance between the two terminals formed on the nonmagnetic metal layer is proportional to the electromotive force.

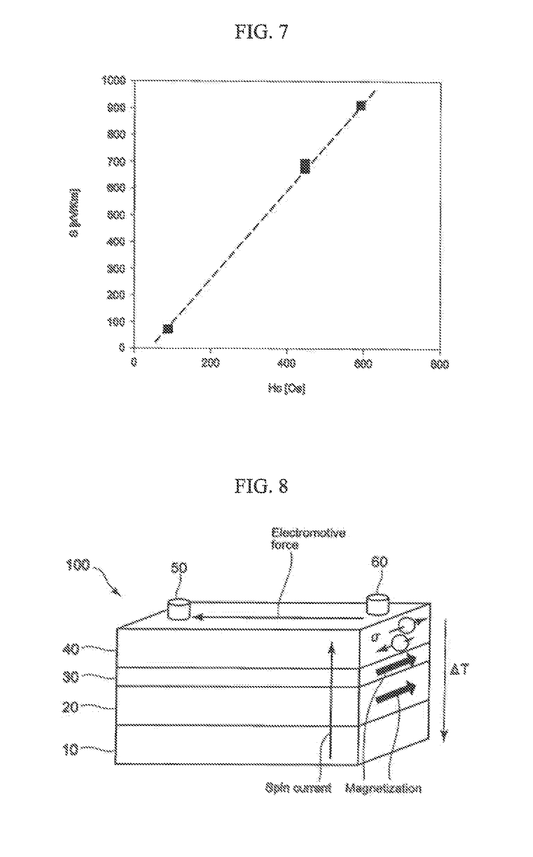

FIG. 7 shows a plot of the results shown table 2 for the comparative example 1 and working examples 1 and 2. FIG. 7 shows the spin Seebeck coefficient increases when the coercive force He increases.

From the above results, the inventors found that it was effective for the insulated ferromagnetic layer 20 to use the hard magnetic material having the coercive force not less than 300 Oe in order to obtain large electromotive force stably.

Thermoelectric converting elements were fabricated as working examples 4-6. The composition of the thermoelectric converting element 100 was used for the working examples 4 and 5.

### Working Example 4

A composition of the ferrite used for the insulated ferromagnetic layer 20 was changed. The insulated ferromagnetic layer 20 provided with a 200 nm thickness and having a magneto-plumbite hexagonal crystal structure such as CoFe₂O₄, Sr—Fe—O, La—Fe—O, La—Co—Fe—O, Sr—La—Co—Fe—O, Sr—La—Zn—Fe—O or like was formed on a thermal silicon oxide substrate. The insulated ferromagnetic layer 20 consisting of CoFe₂04 having a spinel crystal structure was formed on the thermal silicon oxide substrate. These insulated ferromagnetic layers 20 showed high coercive force from 2500 Oe to 4000 Oe because these structures have the composition of a ferrite magnet. For this reason, the electromotive force being a high-resistance property for magnetic noise and stability could be generated.

### Working example 5

The thickness of the insulated ferromagnetic layer 20 was changed.

A 10 nm and 20 nm thickness of Ni—Zn—Fe—O used for the insulated ferromagnetic layer 20 were fabricated.

A coercive force of the 10 nm thickness of the insulated ferromagnetic layer 20 was 300 Oe, and a coercive force of the 20 nm thickness of the insulated ferromagnetic layer 20 was 320 Oe.

Next, the thickness of the insulated ferromagnetic layer 20 was set to 20 nm, and the composition of the insulated ferromagnetic layer 20 was changed. For each, the coercive force was 1100 Oe for Sr—Fe—O, 1150 for La—Fe—O, 1500 Oe for La—Co—Fe—O, 1460 Oe for Sr—La—Co—Fe—O, 1130 Oe for Sr—La—Zn—Fe—O, and 1340 Oe for CoFe₂O₄. In this working example, the electromotive force could be sufficiently generated.

### Working example 6

The composition of the insulated ferromagnetic layer 20 was changed. As shown in FIG. 8, a metallic ferromagnetic layer 30 was provided between the insulated ferromagnetic layer 20 and the nonmagnetic metal layer 40. The metallic ferromagnetic layer 30 is metal magnetic material including one element selected from a group of Fe, Co, Ni, Cr, and Mn. The thickness of the metallic ferromagnetic layer 30 is from 1 Å to 2 nm. The electromotive force leaks when the thickness of the metallic ferromagnetic layer 30 is larger than this thickness. For this reason, the thickness of the metallic ferromagnetic layer 30 is adjusted depending on specific resistance. The electromotive force increased 1.5 times that of the compositions of the working examples 1-5, compared to a case without using the metallic ferromagnetic layer 30 when a FeCo alloy of 0.15 nm thickness was used for the metallic ferromagnetic layer 30. Magnetization of the metallic ferromagnetic layer 30 and magnetization of the insulated ferromagnetic layer 20 are in same direction. The metallic ferromagnetic layer 30 can be contacted directly to the insulated ferromagnetic layer 20 and the nonmagnetic metal layer 40. Spin current can be propagated sufficiently to the nonmagnetic metal layer 40 because these layers are in contact with each other.

The method of fabricating the insulated ferromagnetic layer 20 is explained next. The magneto-plumbite hexagonal crystal structure or the spinel crystal structure can be fabricated by setting the temperature at 200 degree Celsius−500 degree Celsius during heating of the substrate 10. At this time, the insulated ferromagnetic layer 20 has a coercive force not less than 300 Oe.

A vacuum deposition method, non-electrolytic plating method, and a method that smashes a sintered compact with ball milling and mixes the smashed sintered compact into solvent and applies it to the substrate can be used for fabricating the insulated ferromagnetic layer 20. After fabricating the insulated ferromagnetic layer 20, the magneto-plumbite hexagonal crystal structure can be obtained after heating the insulated ferromagnetic layer 20 at not less than 700 degree Celsius and not more than 1200 degree Celsius. The spinel crystal structure can be obtained after heating the insulated ferromagnetic layer 20 at not less than 100 degree Celsius and not more than 350 degree Celsius. At this time, the insulated ferromagnetic layer 20 has a coercive force not less than 300 Oe.

A magnetic field larger than the coercive force of the insulated ferromagnetic layer 20 is applied to the insulated ferromagnetic layer 20 in order to obtain the insulated ferromagnetic layer 20 having a single magnetic domain. If the coercive force of the insulated ferromagnetic layer 20 is 300 Oe, the insulated ferromagnetic layer 20 can have the single magnetic domain by applying an external magnetic field of not less than 1000 Oe to the insulated ferromagnetic layer 20. If the external magnetic field is not less than 5000 Oe, the insulated ferromagnetic layer 20 can have the single magnetic domain more easily. A pulse magnetic field which applies a magnetic field for a short time can be used for the external magnetic field.

Although the exemplary embodiments of the present invention have been described above, these embodiments are presented just as examples, and it is not intended to limit a range of the invention. New embodiments may be carried out with other various modes, and a variety of omissions, replacements, and modifications may be made within a range that does not deviate from the invention. These embodiments and their modifications are included in the scope of the claims of the invention and them equivalents.

What is claimed is:

1. A thermoelectric converting element, comprising:
a substrate;
a nonmagnetic metal layer; and
an insulated ferromagnetic layer provided between the substrate and the nonmagnetic metal layer and having a magnetization fixed in a plane direction of the insulated ferromagnetic layer, the insulating ferromagnetic layer comprising a hard magnetic material.

2. The thermoelectric converting element of claim 1, further comprising:
two terminals provided on the nonmagnetic metal layer and spaced apart along in a direction intersecting with the magnetization of the insulated ferromagnetic layer.

3. The thermoelectric converting element of claim 1, further comprising:
a metallic ferromagnetic layer provided between the insulated ferromagnetic layer and the nonmagnetic metal layer.

4. The thermoelectric converting element of claim 2, further comprising:
a metallic ferromagnetic layer provided between the insulated ferromagnetic layer and the nonmagnetic metal layer.

5. The thermoelectric converting element of claim 4, wherein a magnetization of the metallic ferromagnetic layer is in a same direction of the magnetization of the insulated ferromagnetic layer.

6. The thermoelectric converting element of claim 1, wherein a coercive force of the hard magnetic material is not less than 300 Oe.

7. The thermoelectric converting element of claim 1, wherein the hard magnetic material is an oxide including Fe not less than 25% at and oxygen not less than 55% at and including at least one element selected from a group of Sr, La, Co, Zn, and Ba.

8. The thermoelectric converting element of claim 2, wherein the hard magnetic material is an oxide including Fe not less than 25% at and oxygen not less than 55% at and including at least one element selected from a group of Sr, La, Co, Zn, and Ba.

9. The thermoelectric converting element of claim 3, wherein the hard magnetic material is an oxide including Fe not less than 25% at and oxygen not less than 55% at and including at least one element selected from a group of Sr, La, Co, Zn, and Ba.

10. The thermoelectric converting element of claim 4, wherein the hard magnetic material is an oxide including Fe not less than 25% at and oxygen not less than 55% at and including at least one element selected from a group of Sr, La, Co, Zn, and Ba.

11. The thermoelectric converting element of claim 1, wherein the hard magnetic material is Sr—Fe—O, La—Fe—O, La—Co—Fe—O, Sr—La—Co—Fe—O, Sr—La—Zn—Fe—O, Co—Fe—O, or Ni—Zn—Fe—O.

12. The thermoelectric converting element of claim 1, wherein the hard magnetic material is SrFe₁₂O₁₉, LaFe₁₂O₁₉, LaCo₍ₓ₎Fe₍₁₂₋ₓ₎O₁₉ (0<x<2), Sr_{(y)}La_{(1-y)}Co₍ₓ₎Fe₍₁₂₋ₓ₎O19 (0<x<2, 0<y<1), Sr_{(y)}La_{(1-y)}Zn₍ₓ₎Fe₍₁₂₋ₓ₎O₁₉ (0<x<2, 0<y<1), CoFe₂O₄, or Ni₍ₓ₎Zn₍₁₋ₓ₎Fe₂O₄ (0<x<1).

13. The thermoelectric converting element of claim 1, wherein the hard magnetic material is a magneto-plumbite hexagonal crystal structure or a spinel crystal structure.
